(19) United States
(12) Patent Application Publication
(10) Pub. No.: US 2021/0376123 A1
(43) Pub. Date: Dec. 2, 2021

(54) SUBSTRATE PROCESSING METHOD FOR FORMING INNER SPACERS IN A NANO-SHEET DEVICE

(71) Applicant: Tokyo Electron Limited, Tokyo (JP)

(72) Inventors: Shimpei YAMAGUCHI, Tokyo (JP); Atsushi TSUBOI, Tokyo (JP); Atsushi ENDO, Yamanashi (JP); Masanobu IGETA, Tokyo (JP); Masaru SUGIMOTO, Hillsboro, OR (US); Luis FERNANDEZ, Billerica, MA (US)

(73) Assignee: Tokyo Electron Limited, Tokyo (JP)

(21) Appl. No.: 17/329,178

(22) Filed: May 25, 2021

Related U.S. Application Data
(60) Provisional application No. 63/030,093, filed on May 26, 2020.

(51) Int. Cl. H01L 29/66; H01L 29/06; H01L 29/423; H01L 29/786; H01L 21/02

(52) U.S. Cl. CPC H01L 29/66553; H01L 29/0665; H01L 29/42392; H01L 29/66742; H01L 21/0259; H01L 21/02532; H01L 29/78696

(57) ABSTRACT

A method including depositing a dielectric film on a substrate including stacked structures with recessed portions formed on side surfaces of each of the stacked structures, wherein the dielectric film is deposited so that the stacked structures are covered at a thickness which is equal to or less than half a width of the recessed portions; filling a trench or trenches that are located between the stacked structures with a sacrificial film; etching the sacrificial film along the stacked structures; etching the dielectric film so that the dielectric film is etched more than the sacrificial film; removing the sacrificial film; after the removing of the sacrificial film, depositing a dielectric film to a thickness equal to or less than half the width of the recessed portions; and etching the deposited dielectric film, on a condition that the deposited dielectric film remains in the recessed portions.

### CROSS-REFERENCE TO RELATED APPLICATION

This application is related to provisional application Ser. No. 63/030,093 filed on May 26, 2020, the entire contents of which is incorporated by reference herein.

### BACKGROUND

### Technical Field

The present disclosure relates to substrate processing methods and substrate processing devices for forming inner spacers in a nano-sheet device.

### SUMMARY

An exemplary embodiment is disclosed which provides a method including depositing a dielectric film on a substrate including stacked structures with recessed portions formed on side surfaces of each of the stacked structures, wherein the dielectric film is deposited so that the stacked structures are covered at a thickness which is equal to or less than half a width of the recessed portions; filling a trench or trenches that are located between the stacked structures with a sacrificial film; etching the sacrificial film along the stacked structures; etching the dielectric film so that the dielectric film is etched more than the sacrificial film; removing the sacrificial film; after the removing of the sacrificial film, depositing a dielectric film to a thickness equal to or less than half the width of the recessed portions; and etching the deposited dielectric film, on a condition that the deposited dielectric film remains in the recessed portions.

An exemplary embodiment is disclosed which provides a method including forming a sacrificial film on side surfaces of stacked structures located on a multilayer film, wherein the multilayer film has alternating first films and second films; forming a trench or trenches on the multilayer film by anisotropic etching to etch the multilayer film along a side surface of the sacrificial film; recessing the first films of the multilayer film in a direction perpendicular to a thickness direction of the first films to form a recess or recesses; removing the sacrificial film formed on the side surfaces of the stacked structures; forming the dielectric film on the side surfaces of the stacked structures and filling a trench or trenches on the multilayer film with the dielectric film; and performing anisotropic etching along the stacked structures having the side surfaces on which the dielectric film is formed so that the dielectric film filled in the trench or trenches of the multilayer film is etched.

The foregoing paragraphs have been provided by way of general introduction, and are not intended to limit the scope of the following claims. The described embodiments, together with further advantages, will be best understood by reference to the following detailed description taken in conjunction with the accompanying drawings.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 illustrates a cross-sectional view of a conventional nano-sheet device structure.

FIG. 2 illustrates a cross-sectional view of a nano-sheet device during a manufacturing procedure according to an exemplary embodiment.

FIG. 3 illustrates a cross-sectional view of a nano-sheet device during a manufacturing procedure according to the exemplary embodiment.

FIG. 4 illustrates a cross-sectional view of a nano-sheet device during a manufacturing procedure according to the exemplary embodiment.

FIG. 5 illustrates a cross-sectional view of a nano-sheet device during a manufacturing procedure according to the exemplary embodiment.

FIG. 6 illustrates a cross-sectional view of a nano-sheet device during a manufacturing procedure according to an exemplary embodiment.

FIG. 7 illustrates a cross-sectional view of a nano-sheet device during a manufacturing procedure according to the exemplary embodiment.

FIG. 8 illustrates a cross-sectional view of a nano-sheet device during a manufacturing procedure according to the exemplary embodiment.

FIG. 9 illustrates a cross-sectional view of a nano-sheet device during a manufacturing procedure according to the exemplary embodiment.

FIG. 10 illustrates a cross-sectional view of a nano-sheet device during a manufacturing procedure according to the exemplary embodiment.

FIG. 11 illustrates a cross-sectional view of a nano-sheet device during a manufacturing procedure according to the exemplary embodiment.

FIG. 12 illustrates a cross-sectional view of a nano-sheet device during a manufacturing procedure according to the exemplary embodiment.

FIG. 13 illustrates a cross-sectional view of a nano-sheet device during a manufacturing procedure according to the exemplary embodiment.

FIG. 14 illustrates a cross-sectional view of a nano-sheet device during a manufacturing procedure according to the exemplary embodiment.

FIG. 15 illustrates a cross-sectional view of a nano-sheet device during a manufacturing procedure according to the exemplary embodiment.

FIG. 16 illustrates a cross-sectional view of a nano-sheet device during a manufacturing procedure according to an exemplary embodiment.

FIG. 17 illustrates a cross-sectional view of a nano-sheet device during a manufacturing procedure according to the exemplary embodiment.

FIG. 18 illustrates a cross-sectional view of a nano-sheet device during a manufacturing procedure according to the exemplary embodiment.

FIG. 19 illustrates a cross-sectional view of a nano-sheet device during a manufacturing procedure according to the exemplary embodiment.

FIG. 20 illustrates a cross-sectional view of a nano-sheet device during a manufacturing procedure according to the exemplary embodiment.

FIG. 21 illustrates a cross-sectional view of a nano-sheet device during a manufacturing procedure according to the exemplary embodiment.

FIG. 22 illustrates a method of manufacturing a nano-sheet device according to an exemplary embodiment.

FIG. 23 illustrates a method of manufacturing a nano-sheet device according to an exemplary embodiment.

FIG. 24 is diagram of an exemplary capacitively coupled plasma (CCP) type plasma system.

FIG. 25 is a block diagram of a computer-based system used to control processes performed in embodiments according to the present disclosure.

### DETAILED DESCRIPTION

The description set forth below in connection with the appended drawings is intended as a description of various embodiments of the disclosed subject matter and is not necessarily intended to represent the only embodiment(s). In certain instances, the description includes specific details for the purpose of providing an understanding of the disclosed subject matter. However, it will be apparent to those skilled in the art that embodiments may be practiced without these specific details. In some instances, well-known structures and components may be shown in block diagram form in order to avoid obscuring the concepts of the disclosed subject matter.

Reference throughout the specification to “one embodiment” or “an embodiment” means that a particular feature, structure, characteristic, operation, or function described in connection with an embodiment is included in at least one embodiment of the disclosed subject matter. Thus, any appearance of the phrases “in one embodiment” or “in an embodiment” in the specification is not necessarily referring to the same embodiment. Furthermore, references to “one embodiment” of the present invention are not intended to be interpreted as excluding the existence of additional embodiments that also incorporate the recited features. Further, the particular features, structures, characteristics, operations, or functions may be combined in any suitable manner in one or more embodiments. Further, it is intended that embodiments of the disclosed subject matter can and do cover modifications and variations of the described embodiments. It must be noted that, as used in the specification and the appended claims, the singular forms “a,” “an,” and “the” include plural referents unless the context clearly dictates otherwise. That is, unless clearly specified otherwise, as used herein the words “a” and “an” and the like carry the meaning of “one or more.” Additionally, it is to be understood that terms such as “left,” “right,” “top,” “bottom,” “front,” “rear,” “side,” “height,” “length,” “width,” “upper,” “lower,” “interior,” “exterior,” “inner,” “outer,” and the like that may be used herein, merely describe points of reference and do not necessarily limit embodiments of the disclosed subject matter to any particular orientation or configuration. Furthermore, terms such as “first,” “second,” “third,” etc., merely identify one of a number of portions, components, points of reference, operations and/or functions as described herein, and likewise do not necessarily limit embodiments of the disclosed subject matter to any particular configuration or orientation.

The present disclosure relates to substrate processing methods and substrate processing devices for forming inner spacers in a nano-sheet device. A fin-type field-effect transistor (FinFET) is a non-planar device structure that may be more densely packed in an integrated circuit than planar field-effect transistors. A FinFET may include a fin consisting of a solid unitary body of semiconductor material, heavily-doped source/drain regions formed in sections of the body, and a gate electrode that wraps about a channel located in the fin body between the source/drain regions. The arrangement between the gate structure and fin body improves control over the channel and reduces the leakage current when the FinFET is in its ‘Off’ state in comparison with planar transistors. This, in turn, enables the use of lower threshold voltages than in planar transistors, and results in improved performance and reduced power consumption.

The document VLSI Symposium 2017, IBM, Loubet, et al., entitled “Stacked Nanosheet Gate-All-Around Transistor to Enable Scaling Beyond FinFET”, 2017 Symposium on VLSI Technology Digest of Technical Papers, T230-T231, describes FinFET formation using nanosheets, and is incorporated herein by reference in its entirety.

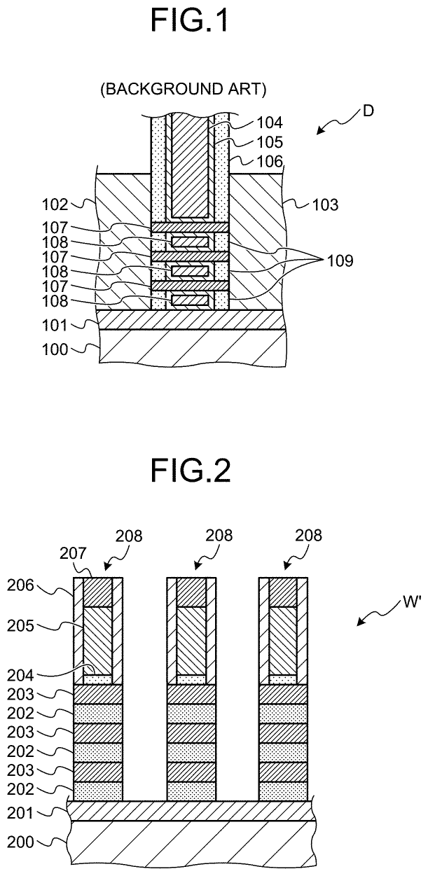

FIG. 1 shows a nano-sheet device D that can suppress short-channel-effect by allowing a nano-sheet channel 107 formed of nanosheet to be surrounded by gate electrodes 104 and 108 from all directions in a cross-section perpendicular to a channel length direction. An inner spacer 109 is provided between the gate electrode 108 and a source/drain electrode 102, 103 to ensure insulation. Also, in FIG. 1, the nan-sheet device includes an insulating layer 101 that is in contact with a silicon substrate 100, a gate dielectric film 105, and a spacer 106.

In an exemplary embodiment, the inner spacer 109 can be fabricated by a method in which a first step includes alternately depositing germanium-containing silicon films 202 and silicon-containing films 203 on a silicon substrate 200 including an insulation layer 201, and forming a gate electrode structure 208 thereon (the gate electrode structure 208 can also be referred to as a stacked structure 208 throughout). The gate electrode structure 208 includes a dielectric film 204, a gate electrode 205, a spacer 206, and a mask 207. Next, as seen in FIG. 2, anisotropic etching is performed on the wafer W′ such that a multilayer film including the germanium-containing silicon films 202 and the silicon-containing films 203 is etched along the gate electrode structure 208. The dielectric film 204 and the spacer 206 can be, for example, SiN, SiOC, SiOCN, etc.

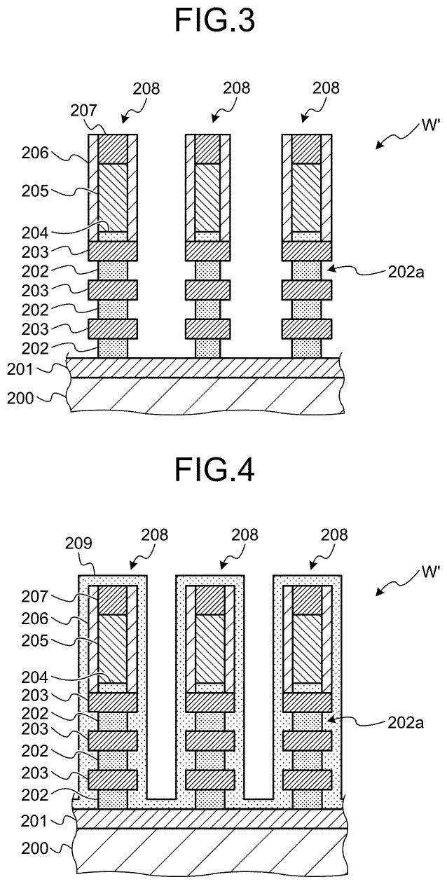

FIG. 3 shows that isotropic etching (such as, for example, wet etching or gas etching) is performed to recess the germanium-containing silicon film 202. As a result, a recessed portion 202a is formed on the germanium-containing silicon film 202.

FIG. 4 shows that a dielectric film 209, which serves as an inner spacer, is conformally deposited by, for example, Atomic Layer Deposition (ALD), Chemical Vapor Deposition (CVD), etc.

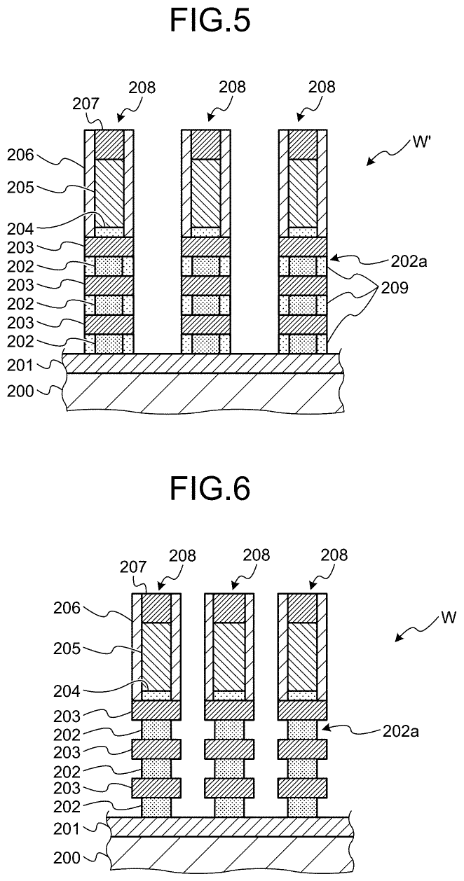

In FIG. 5, isotropic etching (e.g., wet etching, gas etching, etc.) is performed to remove only a part of the dielectric film 209. This allows the dielectric film 209 to remain in the recessed portion 202a of the germanium-containing silicon film 202, thereby forming an inner spacer. However, because recent high-density semiconductor devices have reduced spacing between gate electrode structures 208, the step of FIG. 4 in which the dielectric film 209 is conformally deposited may cause the trench between the gate electrode structures 208 to be filled with the dielectric film 209. If the trench between the gate electrode structures 208 is filled with the dielectric film 209, it is difficult to allow the dielectric film 209 to remain on the recessed portion 202a of the germanium-containing silicon film 202 while removing the dielectric film 209 on other portions by the isotropic etching performed in the step shown in FIG. 5. As a result, an exemplary embodiments of the present disclosure provide methods for forming an inner spacer for a nanosheet having a scaled down gate pitch (i.e., the space between adjacent gate electrode structures 208 is small). A first exemplary method will be described with respect to FIGS. 6-15 and a second exemplary method will be described with respect to FIGS. 16-21.

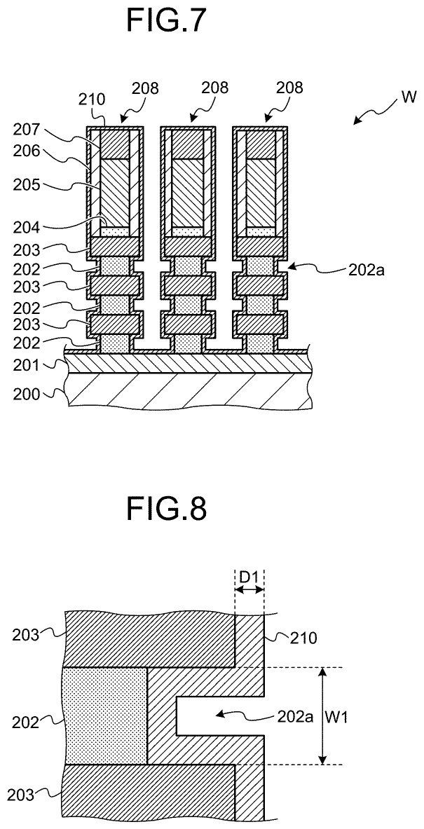

FIG. 6 shows a state of a wafer W after the steps described above with respect to FIGS. 2 and 3 have been performed and is the starting point. Using the state of the wafer W in FIG. 6, a dielectric film 210, which serves as an inner spacer, is conformally deposited by, for example, ALD, CVD, etc. (FIG. 7). The dielectric film 210 is also deposited on the recessed portion 202a of the germanium-containing silicon film 202. In an exemplary embodiment, the dielectric film 210 can be, for example, SiN, SiOC, SiOCN, etc.

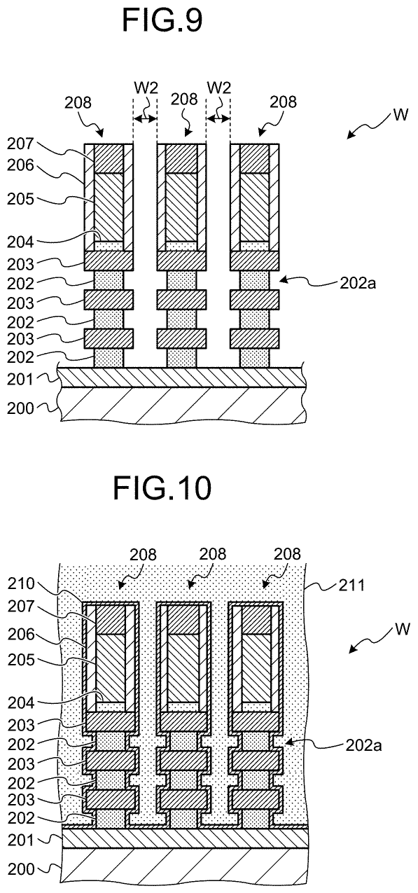

In an exemplary embodiment, as seen in FIG. 8, the thickness D1 of the dielectric film 210 is equal to or less than half the width W1 of the recessed portion 202a formed on the germanium-containing silicon film 202. If the thickness D1 of the dielectric film 210 is half the width W1 of the recessed portion 202a, the recessed portion 202a may be filled with the dielectric film 210 by depositing the dielectric film 210 once. This can reduce the time used for filling the recessed portion 202a with the dielectric film 210. Thus, in an exemplary embodiment, the thickness D1 of the dielectric film 210 can be half the width W1 of the recessed portion 202a. An advantageous feature of the methods of the present disclosure is that the trench between the gate electrode structures 208 is prevented from being filled with the dielectric film 210, even when a gate pitch is scaled down (i.e., even when the distance between the gate electrode structures is small (e.g., a gate pitch of 50 mm or less). Thus, in an exemplary embodiment, the thickness D1 of the dielectric film 210 is equal to or less than half of the width W2 and, for example, may be equal to or less than a quarter of the width W2 (see FIG. 9) of the trench between the gate electrode structures 208 (spacers 206).

In FIG. 10, the trench is filled between the gate electrode structures 208 with a sacrificial film 211. The sacrificial film 211 is also filled in the recessed portion 202a of the germanium-containing silicon film 202 on which the dielectric film 210 is deposited. In an exemplary embodiment, the sacrificial film 211 can be, for example, a carbon film. In an exemplary embodiment, the sacrificial film 211 can be, for example, formed by spin-on processing.

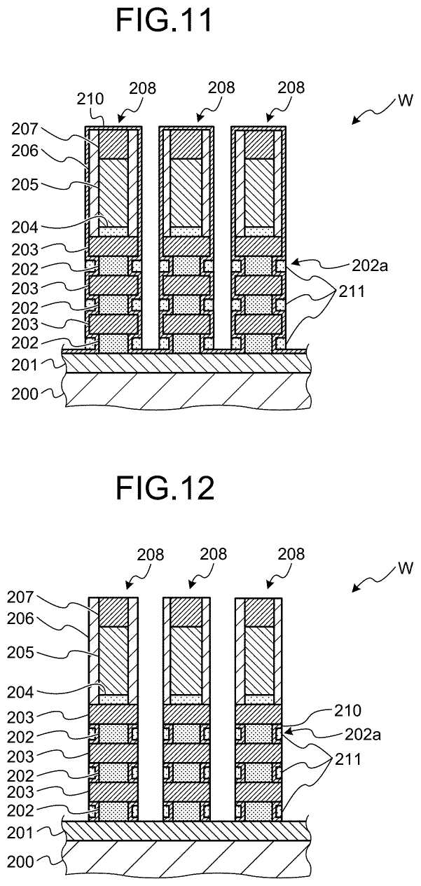

Next, as seen in FIG. 11, the sacrificial film 211 is etched along the gate electrode structure 208 by anisotropic etching. This allows removal of the sacrificial film 211, leaving the sacrificial film 211 in the recessed portion 202a of the germanium-containing silicon film 202.

Next, as seen in FIG. 12, isotropic etching is performed (for example, wet etching, gas etching, etc.) to remove the dielectric film 210. This allows removal of the dielectric film 210, leaving the dielectric film 210 in the recessed portion 202a of the germanium-containing silicon films 202.

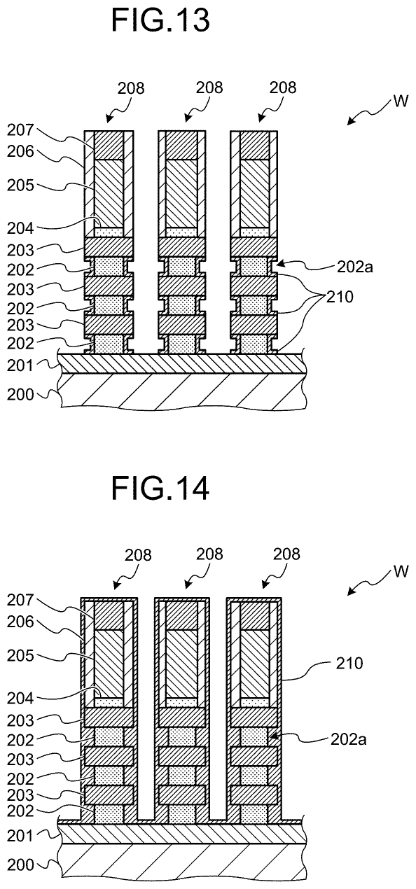

Next, as seen in FIG. 13, isotropic etching is performed to remove the sacrificial film 211 remaining in the recessed portion 202a of the germanium-containing silicon film 202. In an exemplary embodiment, the isotropic etching is, for example, ashing using plasma.

Next, as seen in FIG. 14, the dielectric film 210 is conformally deposited again by, for example, ALD, CVD, etc. The thickness of the dielectric film 210 formed in this step can be equal to or greater/less than the thickness of the dielectric film 210 formed in the step described above with respect to FIG. 7, as long as it is equal to or less than half the width W1 of the recessed portion 202a formed on the germanium-containing silicon film 202.

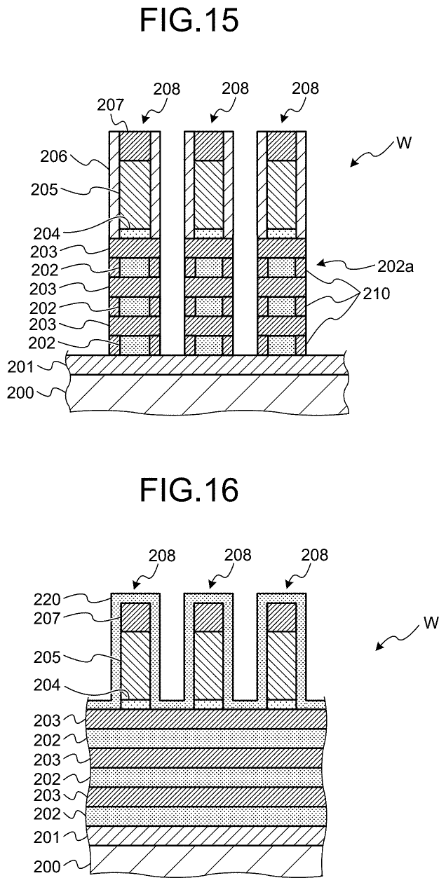

Next, as seen in FIG. 15, the dielectric film 210 is removed by isotropic etching, such as wet etching or gas etching, on the condition that the dielectric film 210 remains in the recessed portion 202a of the germanium-containing silicon film 202. This allows the recessed portion 202a of the germanium-containing silicon film 202 to be filled with the dielectric film 210, which serves as an inner spacer. If the recessed portion 202a is not sufficiently filled with the dielectric film 210 after the step described with respect to FIG. 14, then steps associated with FIGS. 10-13 are repeated.

Another exemplary method will now be described with respect to FIGS. 16-21. In FIG. 16, germanium-containing silicon films 202 and silicon-containing films 203 are alternately deposited on a silicon substrate 200 including an insulation layer 201, and a ridged gate electrode structure 208 is formed thereon. Then, a sacrificial film 220 is conformally deposited by, for example, ALD, CVD, etc. The thickness of the sacrificial film 220 can be, for example, 6 to 8 nm inclusive. The sacrificial film 220 can be a carbon-containing film but is not limited thereto, and can be any film as long as it is easily removable.

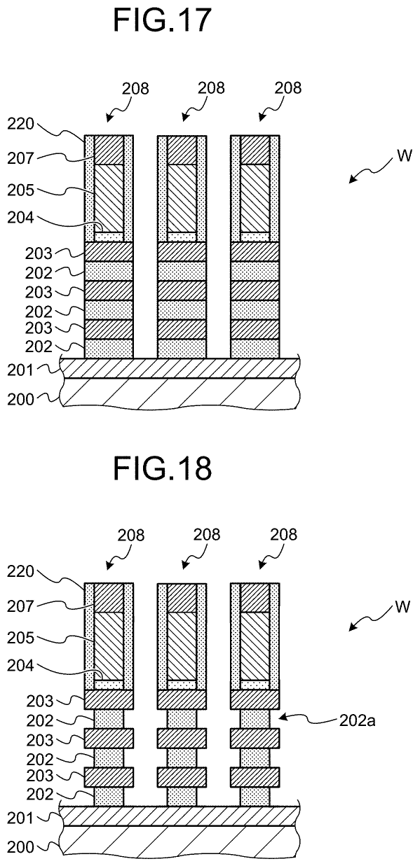

Next, as seen in FIG. 17, anisotropic etching is performed such that a multilayer film including the germanium-containing silicon films 202 and the silicon-containing films 203 is etched along side surfaces of the sacrificial film 220 deposited on the gate electrode structure 208. That is, the vertical sidewalls of the gate electrode structure 208 are straight and even.

Next, as seen in FIG. 18, isotropic etching (for example, wet etching, gas etching, etc.) is performed to recess the germanium-containing silicon film 202 (i.e. form recessed portions 202a). Thus, the germanium-containing silicon film 202 has a recessed portion or portions 202a formed thereon.

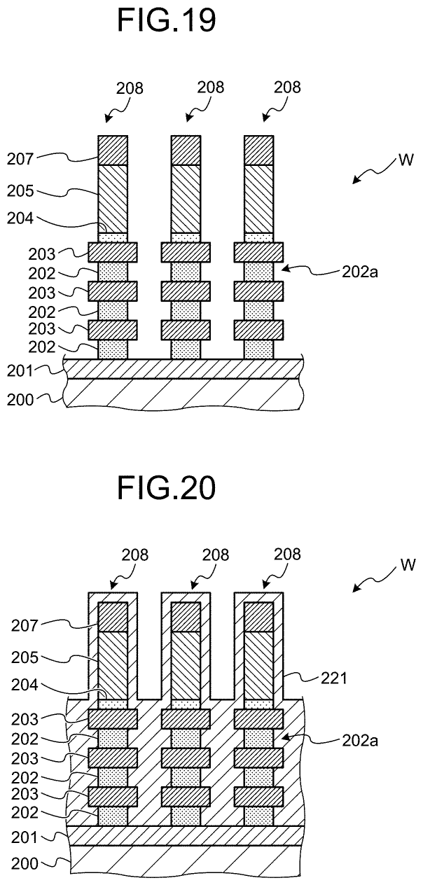

Next, as seen in FIG. 19, isotropic etching is performed to remove the sacrificial film 220 formed on the sidewall of the gate electrode structure 208. In an exemplary embodiment, the isotropic etching is, for example, ashing using plasma.

Next, as seen in FIG. 20, a dielectric film 221, which serves as an inner spacer is conformally deposited by, for example, ALD, CVD, etc. The dielectric film 221 is also filled in the recessed portion 202a of the germanium-containing silicon film 202. In an exemplary embodiment, the dielectric film 221 can be, for example, SiN, SiOC, SiOCN, etc. The thickness of the dielectric film 221, for example, may be same as the sacrificial film 220 and can be 6 to 8 nm inclusive. This allows for the etching of the dielectric film 221 formed on a lower part between the gate electrode structures 208 by anisotropic etching in the next step.

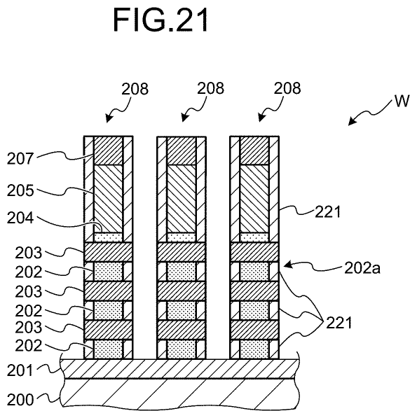

Next, as seen in FIG. 21, anisotropic etching is performed to etch the dielectric film 221 along the gate electrode structure 208. Thus, the vertical sidewalls of the gate electrode structures 208 are even and flat. This allows both a spacer on the side surface of the gate electrode structure 208 and an inner spacer in the recessed portion 202a of the germanium-containing silicon film 202 to be formed in this step. If the thickness of the spacer on the side surface of the gate electrode 208 is reduced to have a thickness less than the thickness of the inner spacer in the recessed portion 202a, this step can be performed again after performing isotropic etching to etch the dielectric film 221 on the side surface of the gate electrode structure 208 to a desired thickness. The aspect ratio of a trench to be formed by anisotropic etching can be reduced to be less than the aspect ratio of the trench between the gate electrode structures 208 filled with the dielectric film 221. Thus, a well-shaped trench can be formed.

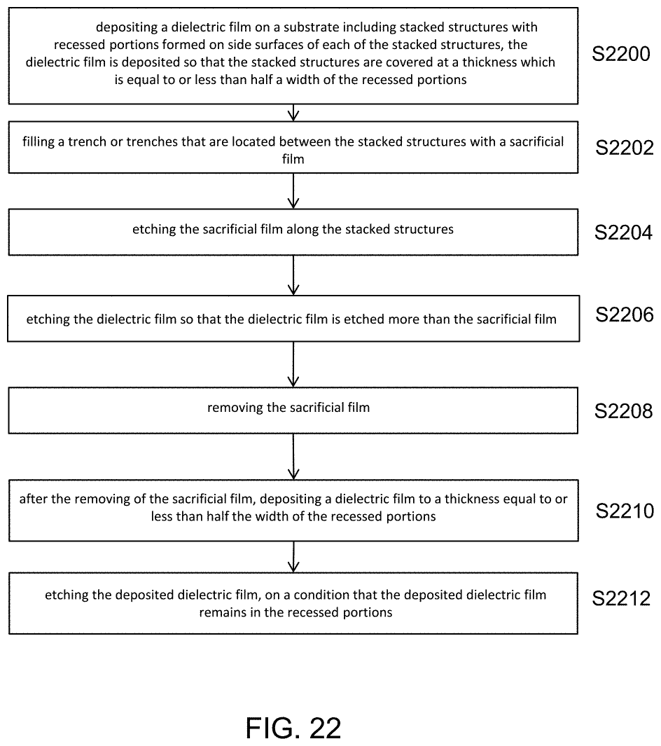

FIG. 22 shows a flow chart of steps of the method described above with respect to FIGS. 6-15. The method includes a step (S2200) of depositing a dielectric film 210 on a substrate 200 including stacked structures 208 with recessed portions 202a formed on side surfaces of each of the stacked structures 208. The dielectric film 210 is deposited so that the stacked structures 208 are covered at a thickness which is equal to or less than half a width W1 of the recessed portions 208. See FIG. 7. Step S2202 includes filling a trench or trenches that are located between the stacked structures 208 with a sacrificial film 211. See FIG. 10. Step S2204 includes etching the sacrificial film 211 along the stacked structures 208. See FIG. 11. Step S2206 includes etching the dielectric film 210 so that the dielectric film 210 is etched more than the sacrificial film 211. See FIG. 12. Step S2208 includes removing the sacrificial film 211. See FIG. 13. In step S2210 after the removing of the sacrificial film 211, a dielectric film 210 is deposited to a thickness equal to or less than half the width W1 of the recessed portions 202a. Step S2212 includes etching the deposited dielectric film 210, on a condition that the deposited dielectric film 210 remains in the recessed portions 202a.

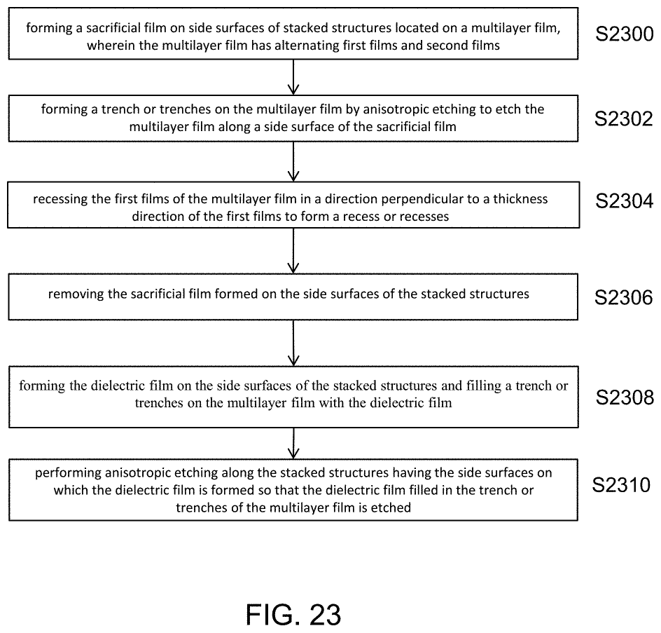

FIG. 23 shows a flow chart of steps of the method described above with respect to FIGS. 16-21. The method includes a step (S2300) of forming a sacrificial film 220 on side surfaces of stacked structures 208 located on a multilayer film (202, 203), wherein the multilayer film has alternating first films 202 and second films 203. See FIG. 16. Step S2302 includes forming a trench or trenches on the multilayer film by anisotropic etching to etch the multilayer film along a side surface of the sacrificial film 220. See FIG. 17. Step S2304 includes recessing the first films 202 of the multilayer film in a direction perpendicular to a thickness direction of the first films 202 to form a recess or recesses 202a. See FIG. 18. Step S2306 includes removing the sacrificial film 220 formed on the side surfaces of the stacked structures 208. See FIG. 19. Step S2308 includes forming the dielectric film 221 on the side surfaces of the stacked structures 208 and filling a trench or trenches on the multilayer film with the dielectric film 221. See FIG. 20. Step S2310 includes performing anisotropic etching along the stacked structures 208 having the side surfaces on which the dielectric film 221 is formed so that the dielectric film 221 filled in the trench or trenches of the multilayer film is etched. See FIG. 21.

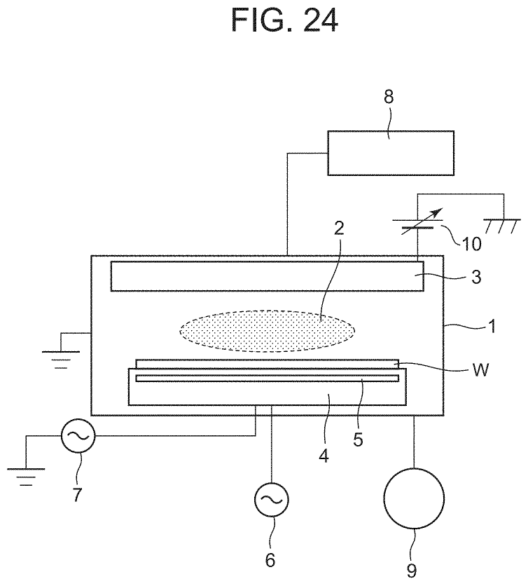

FIG. 24 illustrates an exemplary capacitively coupled plasma (CCP) type plasma system that can be used to perform some or all of the steps of methods described herein. The system of FIG. 24 includes a chamber 1, an upper electrode 3, and a lower electrode 4. RF power is coupled to the lower electrode 4 from RF sources 6 and 7. The power coupling may include differing RF frequencies 6 and 7. The lower electrode 4 includes an electrostatic chuck (ESC) 5 to support and retain a substrate W. A gas source 8 is connected to the chamber 1 to supply processing gases into the chamber 1. An exhaust device 9 such as a turbo molecular pump (TMP) is connected to the chamber 1 to evacuate the chamber 1. Plasma 2 is formed proximate to the substrate W between the upper electrode 3 and the lower electrode 4 as the RF power is supplied to at least one of the upper electrode 3 and the lower electrode 4. Alternatively, multiple RF power sources 6 and 7 may be coupled to a different electrode (e.g., upper electrode 3). Moreover, a variable direct current (DC) power source 10 may be coupled to the upper electrode 3. In an exemplary embodiment, the lower electrode 4 is provided with RF power with a frequency of 13.56 MHz or higher. The lower electrode 4 may or may not be provided with bias power.

In an exemplary embodiment, in the CCP type plasma processing apparatus shown in FIG. 24, the lower electrode 4 is provided with RF power for plasma generation. In an exemplary embodiment, the upper electrode 3 may be provided with RF power. The processing methods disclosed herein are also applicable to a plasma processing apparatus different from the CCP plasma processing apparatus. More specifically, the processing methods may be implemented using any plasma processing apparatus, such as an inductively coupled plasma processing apparatus, a plasma processing apparatus that generates plasma using surface waves such as microwaves, etc.

Control methods and systems described herein may be implemented using computer programming or engineering techniques including computer software, firmware, hardware or any combination or subset thereof, wherein the technical effects may include at least processing of a substrate in a plasma processing apparatus according to the present disclosure.

Control aspects of the present disclosure may be embodied as a system, a method, and/or a computer program product. The computer program product may include a computer readable storage medium on which computer readable program instructions are recorded that may cause one or more processors to carry out aspects of the embodiment.

The computer readable storage medium may be a tangible device that can store instructions for use by an instruction execution device (processor). The computer readable storage medium may be, for example, but is not limited to, an electronic storage device, a magnetic storage device, an optical storage device, an electromagnetic storage device, a semiconductor storage device, or any appropriate combination of these devices. A non-exhaustive list of more specific examples of the computer readable storage medium includes each of the following (and appropriate combinations): flexible disk, hard disk, solid-state drive (SSD), random access memory (RAM), read-only memory (ROM), erasable programmable read-only memory (EPROM or Flash), static random access memory (SRAM), compact disc (CD or CD-ROM), digital versatile disk (DVD) and memory card or stick. A computer readable storage medium, as used in this disclosure, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described in this disclosure can be downloaded to an appropriate computing or processing device from a computer readable storage medium or to an external computer or external storage device via a global network (i.e., the Internet), a local area network, a wide area network and/or a wireless network. The network may include copper transmission wires, optical communication fibers, wireless transmission, routers, firewalls, switches, gateway computers and/or edge servers. A network adapter card or network interface in each computing or processing device may receive computer readable program instructions from the network and forward the computer readable program instructions for storage in a computer readable storage medium within the computing or processing device.

Computer readable program instructions for carrying out operations of the present disclosure may include machine language instructions and/or microcode, which may be compiled or interpreted from source code written in any combination of one or more programming languages, including assembly language, Basic, Fortran, Java, Python, R, C, C++, C# or similar programming languages. The computer readable program instructions may execute entirely on a user's personal computer, notebook computer, tablet, or smartphone, entirely on a remote computer or computer server, or any combination of these computing devices. The remote computer or computer server may be connected to the user's device or devices through a computer network, including a local area network or a wide area network, or a global network (i.e., the Internet). In some embodiments, electronic circuitry including, for example, programmable logic circuitry, field-programmable gate arrays (FPGA), or programmable logic arrays (PLA) may execute the computer readable program instructions by using information from the computer readable program instructions to configure or customize the electronic circuitry, in order to perform aspects of the present disclosure.

Aspects of the present disclosure are described herein with reference to flow diagrams and block diagrams of methods, apparatus (systems), and computer program products according to embodiments of the disclosure. It will be understood by those skilled in the art that each block of the flow diagrams and block diagrams, and combinations of blocks in the flow diagrams and block diagrams, can be implemented by computer readable program instructions.

The computer readable program instructions that may implement the systems and methods described in this disclosure may be provided to one or more processors (and/or one or more cores within a processor) of a general purpose computer, special purpose computer, or other programmable apparatus to produce a machine, such that the instructions, which execute via the processor of the computer or other programmable apparatus, create a system for implementing the functions specified in the flow diagrams and block diagrams in the present disclosure. These computer readable program instructions may also be stored in a computer readable storage medium that can direct a computer, a programmable apparatus, and/or other devices to function in a particular manner, such that the computer readable storage medium having stored instructions is an article of manufacture including instructions which implement aspects of the functions specified in the flow diagrams and block diagrams in the present disclosure.

The computer readable program instructions may also be loaded onto a computer, other programmable apparatus, or other device to cause a series of operational steps to be performed on the computer, other programmable apparatus or other device to produce a computer implemented process, such that the instructions which execute on the computer, other programmable apparatus, or other device implement the functions specified in the flow diagrams and block diagrams in the present disclosure.

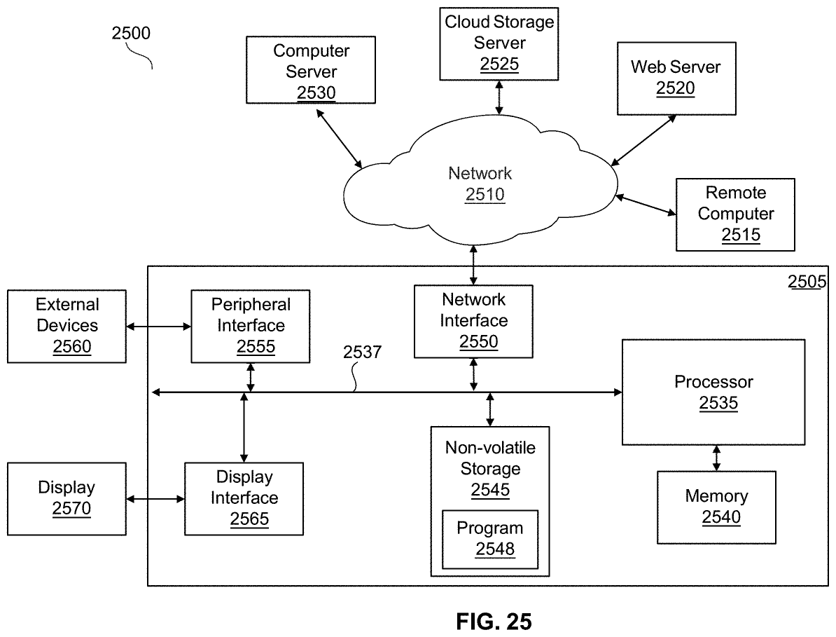

FIG. 25 is a functional block diagram illustrating a networked system 2500 of one or more networked computers and servers. In an embodiment, the hardware and software environment illustrated in FIG. 25 may provide an exemplary platform for implementation of the software and/or methods according to the present disclosure.

Referring to FIG. 25, a networked system 2500 may include, but is not limited to, computer 2505, network 2510, remote computer 2515, web server 2520, cloud storage server 2525 and computer server 2530. In some embodiments, multiple instances of one or more of the functional blocks illustrated in FIG. 25 may be employed.

Additional detail of computer 2505 is shown in FIG. 25. The functional blocks illustrated within computer 2505 are provided only to establish exemplary functionality and are not intended to be exhaustive. And while details are not provided for remote computer 2515, web server 2520, cloud storage server 2525 and computer server 2530, these other computers and devices may include similar functionality to that shown for computer 2505.

Computer 2505 may be a personal computer (PC), a desktop computer, laptop computer, tablet computer, netbook computer, a personal digital assistant (PDA), a smart phone, or any other programmable electronic device capable of communicating with other devices on network 2510.

Computer 2505 may include processor 2535, bus 2537, memory 2540, non-volatile storage 2545, network interface 2550, peripheral interface 2555 and display interface 2565. Each of these functions may be implemented, in some embodiments, as individual electronic subsystems (integrated circuit chip or combination of chips and associated devices), or, in other embodiments, some combination of functions may be implemented on a single chip (sometimes called a system on chip or SoC).

Processor 2535 may be one or more single or multi-chip microprocessors, such as those designed and/or manufactured by Intel Corporation, Advanced Micro Devices, Inc. (AMD), Arm Holdings (Arm), Apple Computer, etc. Examples of microprocessors include Celeron, Pentium, Core i3, Core i5 and Core i7 from Intel Corporation; Opteron, Phenom, Athlon, Turion and Ryzen from AMD; and Cortex-A, Cortex-R and Cortex-M from Arm.

Bus 2537 may be a proprietary or industry standard high-speed parallel or serial peripheral interconnect bus, such as ISA, PCI, PCI Express (PCI-e), AGP, and the like.

Memory 2540 and non-volatile storage 2545 may be computer-readable storage media. Memory 2540 may include any suitable volatile storage devices such as Dynamic Random Access Memory (DRAM) and Static Random Access Memory (SRAM). Non-volatile storage 2545 may include one or more of the following: flexible disk, hard disk, solid-state drive (SSD), read-only memory (ROM), erasable programmable read-only memory (EPROM or Flash), compact disc (CD or CD-ROM), digital versatile disk (DVD) and memory card or stick.

Program 2548 may be a collection of machine readable instructions and/or data that is stored in non-volatile storage 2545 and is used to create, manage and control certain software functions that are discussed in detail elsewhere in the present disclosure and illustrated in the drawings. In some embodiments, memory 2540 may be considerably faster than non-volatile storage 2545. In such embodiments, program 2548 may be transferred from non-volatile storage 2545 to memory 2540 prior to execution by processor 2535.

Computer 2505 may be capable of communicating and interacting with other computers via network 2510 through network interface 2550. Network 2510 may be, for example, a local area network (LAN), a wide area network (WAN) such as the Internet, or a combination of the two, and may include wired, wireless, or fiber optic connections. In general, network 2510 can be any combination of connections and protocols that support communications between two or more computers and related devices.

Peripheral interface 2555 may allow for input and output of data with other devices that may be connected locally with computer 2505. For example, peripheral interface 2555 may provide a connection to external devices 2560. External devices 2560 may include devices such as a keyboard, a mouse, a keypad, a touch screen, and/or other suitable input devices. External devices 2560 may also include portable computer-readable storage media such as, for example, thumb drives, portable optical or magnetic disks, and memory cards. Software and data used to practice embodiments of the present disclosure, for example, program 2548, may be stored on such portable computer-readable storage media. In such embodiments, software may be loaded onto non-volatile storage 2545 or, alternatively, directly into memory 2540 via peripheral interface 2555. Peripheral interface 2555 may use an industry standard connection, such as RS-232 or Universal Serial Bus (USB), to connect with external devices 2560.

Display interface 2565 may connect computer 2505 to display 2570. Display 2570 may be used, in some embodiments, to present a command line or graphical user interface to a user of computer 2505. Display interface 2565 may connect to display 2570 using one or more proprietary or industry standard connections, such as VGA, DVI, DisplayPort and HDMI.

As described above, network interface 2550, provides for communications with other computing and storage systems or devices external to computer 2505. Software programs and data discussed herein may be downloaded from, for example, remote computer 2515, web server 2520, cloud storage server 2525 and computer server 2530 to non-volatile storage 2545 through network interface 2550 and network 2510. Furthermore, the systems and methods described in this disclosure may be executed by one or more computers connected to computer 2505 through network interface 2550 and network 2510. For example, in some embodiments the systems and methods described in this disclosure may be executed by remote computer 2515, computer server 2530, or a combination of the interconnected computers on network 2510.

Data, datasets and/or databases employed in embodiments of the systems and methods described in this disclosure may be stored and or downloaded from remote computer 2515, web server 2520, cloud storage server 2525 and computer server 2530.

In an exemplary embodiment, a method includes depositing a dielectric film 210 on a substrate 200 including stacked structures 208 with recessed portions 202a formed on side surfaces of each of the stacked structures 208. The dielectric film 210 is deposited so that the stacked structures 208 are covered at a thickness which is equal to or less than half a width W1 of the recessed portions 202a. The method also includes filling a trench or trenches that are located between the stacked structures 208 with a sacrificial film 211. The method also includes etching the sacrificial film 211 along the stacked structures 208. The method also includes etching the dielectric film 210 so that the dielectric film 210 is etched more than the sacrificial film 211. The method also includes removing the sacrificial film 211. After the removing of the sacrificial film 211, the method includes depositing a dielectric film 210 to a thickness equal to or less than half the width W1 of the recessed portions 202a. Further, the method includes etching the deposited dielectric film 210, on a condition that the deposited dielectric film 210 remains in the recessed portions 202a.

In an exemplary embodiment, the substrate includes a substrate layer, an insulating layer, alternately layered germanium-containing silicon films and silicon-containing films, and the stacked structures. The alternately layered films are located between the stacked structures and the insulating layer, and the insulating layer is located between the substrate layer and the alternately layered films. The stacked structures each include a dielectric film, a gate electrode, a spacer, and a mask.

In an exemplary embodiment, the width W1 of the recessed portions 202a is a vertical distance between adjacent layers 203 of a same material.

In an exemplary embodiment, the etching of the sacrificial film 211 along the stacked structures 208 is anisotropic etching.

In an exemplary embodiment, the etching of the dielectric film 210 is isotropic etching.

In an exemplary embodiment, the removing of the sacrificial film 211 includes removing of the sacrificial film 211 present in the recessed portions 202a.

In an exemplary embodiment, the thickness of the dielectric film 210 is half the width of the recessed portion 202a.

In an exemplary embodiment, the thickness of the dielectric film 210 is equal to or less than a quarter of a width W2 between adjacent stacked structures 208.

In an exemplary embodiment, the dielectric film 210 is SiN, SiOC, or SiOCN.

In an exemplary embodiment, the sacrificial film 211 is a carbon-containing film.

In an exemplary embodiment, the depositing the dielectric film 210 on the substrate 200, the filling the trench, the etching of the sacrificial film 211, the etching the dielectric film 210, and the removing of the sacrificial film 211 are all repeated one or more times.

In an exemplary embodiment, a method includes forming a sacrificial film 220 on side surfaces of stacked structures 208 located on a multilayer film. The multilayer film has alternating first films 202 and second films 203. The method includes forming a trench or trenches on the multilayer film by anisotropic etching to etch the multilayer film along a side surface of the sacrificial film 220. The method includes recessing the first films 202 of the multilayer film in a direction perpendicular to a thickness direction of the first films 202 to form a recess or recesses 202a. The method includes removing the sacrificial film 220 formed on the side surfaces of the stacked structures 208. The method includes forming the dielectric film 221 on the side surfaces of the stacked structures 208 and filling a trench or trenches on the multilayer film with the dielectric film 221. The method includes performing anisotropic etching along the stacked structures 208 having the side surfaces on which the dielectric film 221 is formed so that the dielectric film 221 filled in the trench or trenches of the multilayer film is etched.

In an exemplary embodiment, the first film 202 is a germanium-containing silicon film, and the second film 203 is a silicon-containing film.

In an exemplary embodiment, the sacrificial film 220 is a carbon-containing film.

In an exemplary embodiment, the thickness of the dielectric film 221 is equal to or greater than half the width W1 of the recess 202a.

In an exemplary embodiment, the width W1 of the recessed portions 202a is a vertical distance between adjacent layers of the second films 203.

In an exemplary embodiment, the thickness of the dielectric film 221 is equal to or larger than 6 nm and equal to or less than 8 nm.

In an exemplary embodiment, the dielectric film 221 is SiN, SiOC, or SiOCN.

In an exemplary embodiment, the sacrificial film 220 is a carbon-containing film.

Having now described embodiments of the disclosed subject matter, it should be apparent to those skilled in the art that the foregoing is merely illustrative and not limiting, having been presented by way of example only. Thus, although particular configurations have been discussed herein, other configurations can also be employed. Numerous modifications and other embodiments (e.g., combinations, rearrangements, etc.) are enabled by the present disclosure and are within the scope of one of ordinary skill in the art and are contemplated as falling within the scope of the disclosed subject matter and any equivalents thereto. Features of the disclosed embodiments can be combined, rearranged, omitted, etc., within the scope of the invention to produce additional embodiments. Furthermore, certain features may sometimes be used to advantage without a corresponding use of other features. Accordingly, Applicant(s) intend(s) to embrace all such alternatives, modifications, equivalents, and variations that are within the spirit and scope of the disclosed subject matter.

### REFERENCE NUMERALS

D nano-sheet device
D1 thickness of the dielectric film 210
W1 width of the recessed portion 202a
W2 width of the trench between the gate electrode structures 208
W′ substrate
100 silicon substrate
101 insulation layer
102 source/drain electrode
103 source/drain electrode
104 gate electrode
105 gate dielectric film
106 spacer
107 nano-sheet channel
108 gate electrode
109 inner spacer
200 silicon substrate
201 insulation layer
202 germanium-containing silicon film
202a recessed portion
203 silicon-containing film
204 dielectric film
205 gate electrode
206 spacer
207 mask
208 gate electrode structure/stacked structure
209 dielectric film
210 dielectric film
211 sacrificial film
220 sacrificial film
221 dielectric film

1. A method comprising:
depositing a first dielectric film on a substrate including stacked structures with recessed portions formed on side surfaces of each of the stacked structures, wherein the first dielectric film is deposited so that the stacked structures are covered at a thickness which is equal to or less than half a width of the recessed portions;
filling a trench or trenches that are located between the stacked structures with a sacrificial film;
etching the sacrificial film along the stacked structures;
etching the first dielectric film so that the first dielectric film is etched more than the sacrificial film;
after etching the first dielectric film, removing the sacrificial film;
after the removing of the sacrificial film, depositing a second dielectric film to a thickness equal to or less than half the width of the recessed portions; and
etching the second deposited dielectric film, on a condition that the deposited second dielectric film remains in the recessed portions.

2. The method of claim 1, wherein the substrate includes a substrate layer, an insulating layer, alternately layered germanium-containing silicon films and silicon-containing films, and the stacked structures,
wherein the alternately layered films are located between the stacked structures and the insulating layer, and the insulating layer is located between the substrate layer and the alternately layered films, and
wherein the stacked structures each include a third dielectric film, a gate electrode, a spacer, and a mask.

3. The method of claim 1, wherein the width of the recessed portions is a vertical distance between adjacent layers of a same material.

4. The method of claim 1, wherein the etching of the sacrificial film along the stacked structures is anisotropic etching.

5. The method of claim 1, wherein the etching of the first dielectric film is isotropic etching.

6. The method of claim 1, wherein the removing of the sacrificial film includes removing of the sacrificial film present in the recessed portions.

7. The method of claim 1, wherein the thickness of the first dielectric film is half the width of the recessed portion.

8. The method of claim 1, wherein the thickness of the first dielectric film is equal to or less than a quarter of a width between adjacent stacked structures.

9. The method of claim 1, wherein the first dielectric film is SiN, SiOC, or SiOCN.

10. The method of claim 1, wherein the sacrificial film is a carbon-containing film.

11. The method of claim 1, wherein the depositing the first dielectric film on the substrate, the filling the trench, the etching of the sacrificial film, the etching the dielectric film, and the removing of the sacrificial film are all repeated one or more times.

12. A method comprising:
forming a sacrificial film on side surfaces of stacked structures located on a multilayer film, wherein the multilayer film has alternating first films and second films;
forming a trench or trenches on the multilayer film by anisotropic etching to etch the multilayer film along a side surface of the sacrificial film;
recessing the first films of the multilayer film in a direction perpendicular to a thickness direction of the first films to form a recess or recesses;
after recessing the first films of the multilayer film, removing the sacrificial film formed on the side surfaces of the stacked structures;
after removing the sacrificial film, forming a dielectric film on the side surfaces of the stacked structures and filling the trench or trenches on the multilayer film with the dielectric film; and
performing anisotropic etching along side surfaces of the dielectric film formed on the side surfaces of the stacked structures so that the dielectric film filled in the trench or trenches of the multilayer film is etched.

13. The method of claim 12, wherein the first films are germanium-containing silicon films, and the second films are silicon-containing films.

14. The method of claim 12, wherein the sacrificial film is a carbon-containing film.

15. The method of claim 12, wherein the thickness of the dielectric film is equal to or greater than half the width of the recess.

16. The method of claim 15, wherein the width of the recessed portions is a vertical distance between adjacent layers of the second films.

17. The method of claim 12, wherein the thickness of the dielectric film is equal to or larger than 6 nm and equal to or less than 8 nm.

18. The method of claim 12, wherein the dielectric film is SiN, SiOC, or SiOCN.

19. The method of claim 16, wherein the sacrificial film is a carbon-containing film.

20. The method of claim 16, wherein the dielectric film is SiN, SiOC, or SiOCN.
